(19) United States
(12) Patent Application Publication
(10) Pub. No.: US 2007/0004050 A1
(43) Pub. Date: Jan. 4, 2007

(54) Method of regenerating substrate

(75) Inventors: Masahiro Ikeda, Kawasaki (JP); Minoru Otani, Kawasaki (JP)

Correspondence Address: BIRCH STEWART KOLASCH & BIRCH, PO BOX 747, FALLS CHURCH, VA, 22040-0747, US

(73) Assignee: Sharp Kabushiki Kaisha, Osaka-shi (JP)

(21) Appl. No.: 11/443,091

(22) Filed: May 31, 2006

(30) Foreign Application Priority Data
May 31, 2005 (JP) 2005-158692

(51) Int. Cl. H01L 21/00; H01L 21/8242

(52) U.S. Cl. 438/4; 438/253

(57) ABSTRACT

For the purpose of readily and thoroughly removing organic material components, in particular such as alignment film and alignment-control projection component, formed on an inorganic material film while minimizing the number of process steps, and reducing damage possibly exerted on the individual layers under the organic material components as possible, so as to allow a color filter (CF) substrate or a TFT substrate to be recycled after being returned back to a state very close to its final form, a CF substrate for example is regenerated by removing an alignment film, a columnar spacer and projection components, all of which being organic material components residing on the upper side of the ITO transparent electrode as an inorganic material film, by wet polishing using an abrasive containing cerium oxide and water.

### CROSS-REFERENCE TO RELATED APPLICATIONS

This application is based upon and claims the benefit of priority from the prior Japanese Patent Application No. 2005-158692, filed on May 31, 2005, the entire contents of which are incorporated herein by reference.

### BACKGROUND OF THE INVENTION

1. Field of the Invention

The present invention relates to a method of regenerating a substrate aiming at regenerating a substrate of a non-conforming article driven out from a fabrication process of liquid crystal display devices, by removing an organic material component causative of the nonconformity.

2. Description of the Related Art

A liquid crystal display device is generally configured as having a pair of substrates each provided with a transparent electrode and so forth, and a li1uid crystal layer held between these substrates, and as driving liquid crystal molecules by applying voltage between the transparent electrodes so as to control the transmissivity of light to thereby effect display.

Recent increase in demands for the liquid crystal display device also diversifies requirements for the liquid crystal display device. Among others, a particularly strong need resides in improvement in the viewing-angle characteristics and display quality. As a technique of satisfying the need, there has been proposed an MVA (multi-domain vertical alignment) mode liquid crystal display device having the liquid crystal molecules vertically aligned therein, wherein the liquid crystal molecules are controlled to have a plurality of directions of inclination under voltage application, with the aid of ridge-like (stripe-patterned) projection components or the like provided on the surface of the substrates, without rubbing alignment films, showing a great success of improving the viewing angle characteristics.

By the way, fabrication process of the liquid crystal display device may yield non-conforming articles due to defects and characteristic failures occurred in the fabrication process. Yield ratio of the device may be low due to variations in the materials, manufacturing apparatuses and process conditions in particular in a period from the initial phase of production to the stabilized phase of production, and therefore a large amount of non-conforming articles may occur. With respect to the non-conforming articles, it is preferable to regenerate the support substrates as possible by removing the non-conforming layers.

Various non-conforming layers have conventionally been removed by chemical peeling using predetermined peeling solutions (see Patent Document 1). For an exemplary case where the alignment film was found to be a non-conforming layer, the alignment film can be removed by dipping the substrate into an alkaline developing solution such as TMAH, an organic solvent such as γ-butyrolactone, or a remover solution such as NMP, for several to several tens of minutes, wherein a sintered alignment film, which is hard to remove, is removed by heating the chemical liquid to 40° C. to 60° C. or around so as to accelerate the reaction.

Alignment-control components typically composed of an organic material such as Novolac resin, formed on an ITO transparent electrode, is also hard to remove by the chemical solution after sintering, similarly to the alignment film, so that such components are removed by ashing such as ozone ashing and plasma ashing, or by dry etching, to thereby regenerate the substrate.

Related arts are disclosed in:

[Patent Document 1] Japanese Patent Application Laid-Open No. 2003-279915; and

[Patent Document 2] Japanese Patent Application Laid-Open No. Hei 11-95019.

Some of the organic materials such as the alignment film for vertical alignment in particular in the MVA-mode liquid crystal display device may, however, not be removed even before being sintered, because they are less likely to allow the chemical liquid for removal to permeate therethrough. Another problem arises in that the heating of the chemical liquid aiming at accelerating the reaction may chemically damage also the underlying color filter layers, resulting in peeling-off of the color filter resin, color fading due to elimination of pigments, increase in surface irregularity of the resin, and surface roughening of the ITO transparent electrodes.

For an exemplary case where organic material components formed on the ITO transparent electrode are removed by plasma ashing, thick organic material components such as projection components (1.4 μm thick) and columnar spacers (3.5 μm thick) cannot completely be removed due to their etchrate typically as slow as 0.2 μm per 30 seconds, often leaving a portion thereof unremoved on the surface as a pattern mark. Still another problem is that a prolonged duration of ashing results in the surface roughening and irregularity similarly to the case of treatment with a chemical liquid.

On the other hand, if the glass substrate should be regenerated by completely removing various films on the substrate using a strong alkali or the like to thereby recover a state of intact glass, it would be necessary to form the color filters, TFT and so forth again on the plane state of the glass substrate, raising a problem of additional needs of a large number of process steps and large costs.

### SUMMARY OF THE INVENTION

The present invention was conceived after consideration on the above-described problems, and an object thereof it to provide a method of regenerating a substrate capable of readily and thoroughly removing organic material components formed on an inorganic material layer, in particular alignment film, alignment-control projection components and so forth, while minimizing as possible the number of process steps and reducing damage possibly exerted on the individual layers under the organic material components, so as to allow a color filter substrate or a TFT substrate to be recycled after being returned back to a state very close to its final form.

A method of regenerating a substrate of the present invention is a method of regenerating a substrate used for a liquid crystal display device, selectively removing, using an inorganic material film formed on the upper portion of the substrate as a polishing stopper layer, only an organic material component formed on the inorganic material film, only by wet polishing using an abrasive.

In the present invention, the organic material components formed on the inorganic material film, such as an alignment film, columnar spacers, alignment-control components and so forth, all of which are sintered resin layers generally difficult to be removed, are removed by polishing as a physical peeling effected over the entire surface, using the inorganic material film such as an ITO film, having a small polishing rate, as a polishing stopper layer. In this case, the organic material components can be removed only by the wet polishing, without being followed by chemical peeling. It is therefore made possible to return the individual substrates back to states very close to those attained in the final process steps, and to regenerate the substrates by a minimum number of process steps, without damaging the quality of underlying ITO layer, color filter layers, TFT layer and so forth, while also suppressing increase in roughening and irregularity on the substrate surface because there is no need of carrying out chemical peeling.

According to one aspect of the method of regenerating a substrate of the present invention, only the organic material component is removed by repeating the polishing a plural number of times, while varying the polishing rate by using different types of the abrasive.

Such polishing repeated a plural number of times makes it possible to efficiently polish even those of the organic material components especially hard to polish, to realize thorough removal-by-polishing finely adapted to various organic material components, and to improve the flatness of the surface of the polished substrate.

### BRIEF DESCRIPTION OF THE DRAWINGS

FIG. 1 is a schematic sectional view showing a CF substrate;

FIGS. 2A to 2C are schematic sectional views sequentially showing process steps of regenerating the CF substrate according to a first embodiment;

FIGS. 3A and 3B are schematic sectional views comparatively showing a finished state of wet polishing of the CF substrate according to the present embodiment and a regenerated state obtained after a conventional chemical peeling process;

FIGS. 4A to 4C are drawings showing, by optical microphotographs, states of the CF substrate taken after the wet polishing according to the first embodiment;

FIGS. 5A to 5C are drawings showing, by electron microphotographs, states of the CF substrate taken after the wet polishing according to the first embodiment;

FIGS. 6A to 6C are schematic sectional views sequentially showing process steps of regenerating the CF substrate according to a modified example of the first embodiment;

FIG. 7 is a schematic sectional view showing a configuration of a TFT substrate;

FIGS. 8A to 8C are schematic sectional views sequentially showing process steps of regenerating the TFT substrate according to a second embodiment; and

FIG. 9 is a schematic sectional view showing a finished state of the wet polishing according to the second embodiment.

### DETAILED DESCRIPTION OF THE PREFERRED EMBODIMENTS

Paragraphs below will detail preferred embodiments applied with the present invention, referring to the attached drawings.

### First Embodiment

This embodiment will exemplify a case where the present invention is adopted to regeneration of a color filter (CF) substrate of a MVA-mode liquid crystal display device.

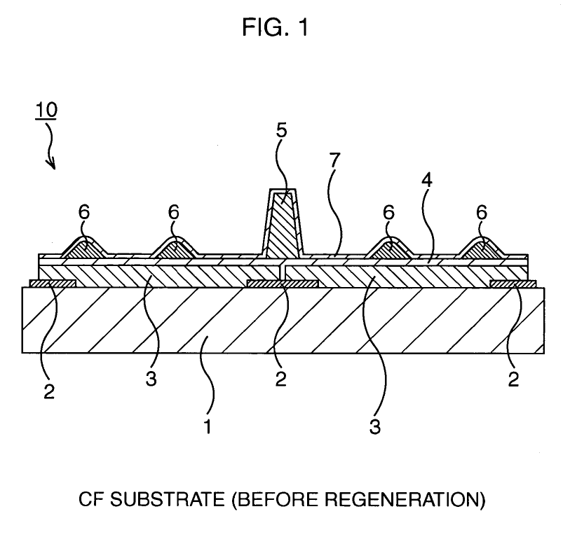

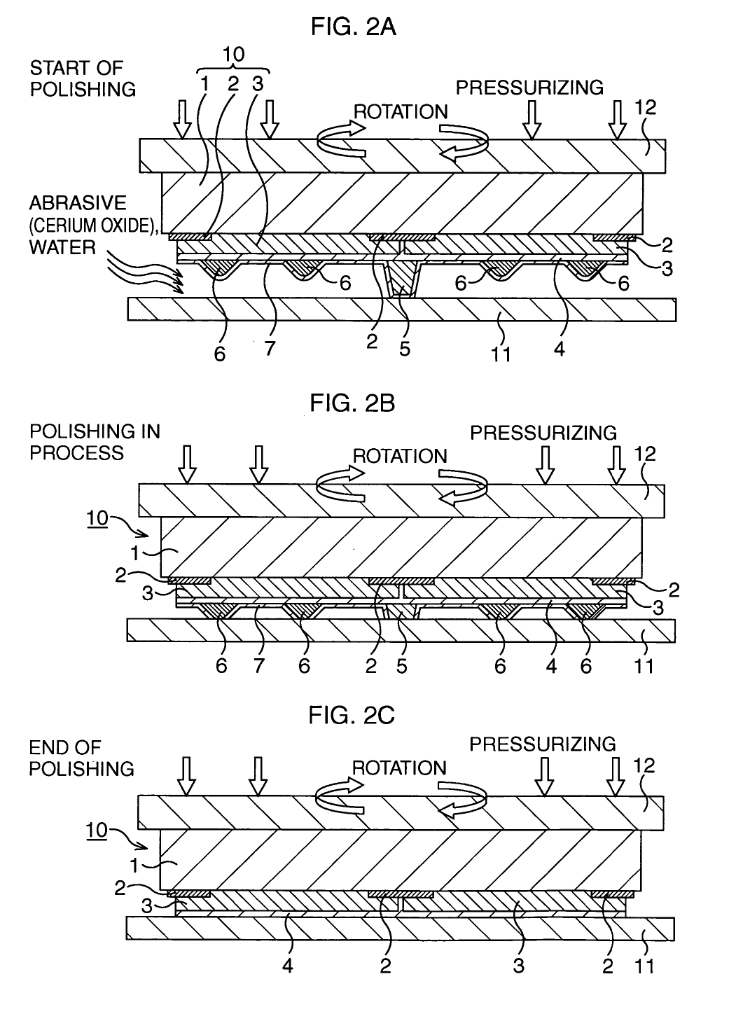

FIG. 1 is a schematic sectional view showing a configuration of the CF substrate, and FIGS. 2A to 2C are schematic sectional views sequentially showing process steps of the method of regenerating the CF substrate according to the first embodiment.

As shown in FIG. 1, the CF substrate 10 has a black matrix formed directly on the surface of a glass substrate 1, by patterning a low-reflection Cr film (approximately 160 nm thick, for example), a resin black layer (approximately 1.2 μm thick, for example) or the like. This embodiment adopts the low-reflection Cr film, referring it to as “low-reflection Cr-BM2”.

Next, on the low-reflection Cr-BM2, patterning of the individual colored resin layers R (red), G (green) and B (blue) are repeated three times, to thereby form color filter layers 3 of, for example, approximately 1.8 μm thick. An ITO transparent electrode 4 of approximately 150 nm thick is further formed so as to cover the color filter layers 3.

Next, on the ITO transparent electrode 4, a columnar spacer 5 of, for example, approximately 3.5 μm high for keeping the thickness of the cell, and ridge-like (stripe-patterned) alignment-control projection components 6 of, for example, approximately 1.4 μm high, typically composed of Novolac resin, are formed by patterning. An alignment film 7 of, for example, approximately 0.1 μm thick, for aligning the liquid crystal molecules on the ITO transparent electrode 4, is then formed so as to cover the columnar spacer 5 and the projection components 6, to thereby configure a CF substrate 10.

In this embodiment, the CF substrate 10 is regenerated by removing the organic material components which reside on the upper side of the ITO transparent electrode 4 as an inorganic material film, that are the alignment film 7, the columnar spacer 5 and the projection components 6.

First, as shown in FIG. 2A, the back surface (lower surface) of the CF substrate 10 is fixed to a substrate holder (substrate stage) 12. While keeping the CF substrate 10 fixed to the substrate holder 12, the CF substrate 10 is then allowed to rotate so as to bring the top surface (upper surface) thereof into contact with a polishing head (polishing stage) 11, as being pressurized by the substrate holder 12. Polishing over the entire surface of the CF substrate 10 is started herein by wet etching, using a cerium oxide-containing abrasive and water. The illustrated example shows polishing of the CF substrate 10 turned upside down from the state shown in FIG. 1.

In the process of polishing, the CF substrate 10 is gradually polished on the surface thereof so as to be removed earlier in the higher portions, as shown in FIG. 2B. In this case, the polishing proceeds so as to remove the alignment film 7 on the columnar spacer 5, the columnar spacer 5, the alignment film 7 on the projection components 6, the projection components 6, and the alignment film 7 on the ITO transparent electrode 4 in this order.

The ITO transparent electrode 4 as an inorganic material film then functions as a polishing stopper layer, as shown in FIG. 2C. The polishing is stopped approximately one minute after the surface of the ITO transparent electrode 4 exposed.

While this embodiment dealt with the case where the acryl-resin-made columnar spacer 5 and the alignment-control projection components 6 were formed on the CF substrate 10, it is also allowable to simply remove the alignment film 7 only, or to remove the columnar spacer only.

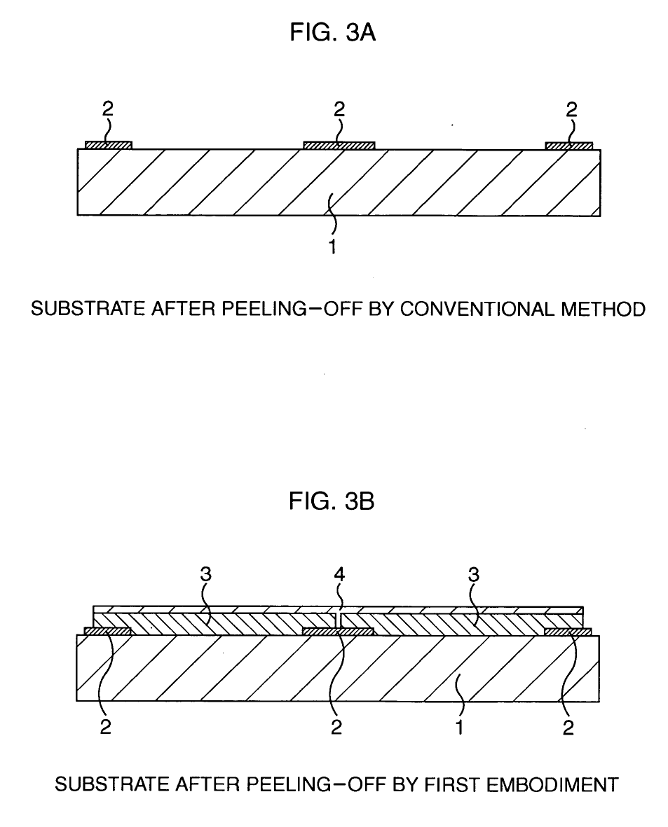

A finished state of the wet polishing of the CF substrate 10 in this embodiment, and a regenerated state obtained after a conventional chemical peeling process for comparison are shown in FIGS. 3A and 3B. FIG. 3A shows a state of the peeling-off obtained by the conventional method, and FIG. 3B shows a state of removal by this embodiment.

The conventional method returns the CF substrate back to a state having the low-reflection Cr-BM2 formed on the glass substrate 1. In contrast to this, the CF substrate 10 in this embodiment is returned back to a state very close to the final form, wherein the color filters 3 and the ITO transparent electrode 4 are stacked on the low-reflection Cr-BM2. As is clear from the above, this embodiment raises no additional need of forming the color filters 3 and the ITO transparent electrode 4 again, and is successful in considerably reducing the number of process steps as compared with the conventional method.

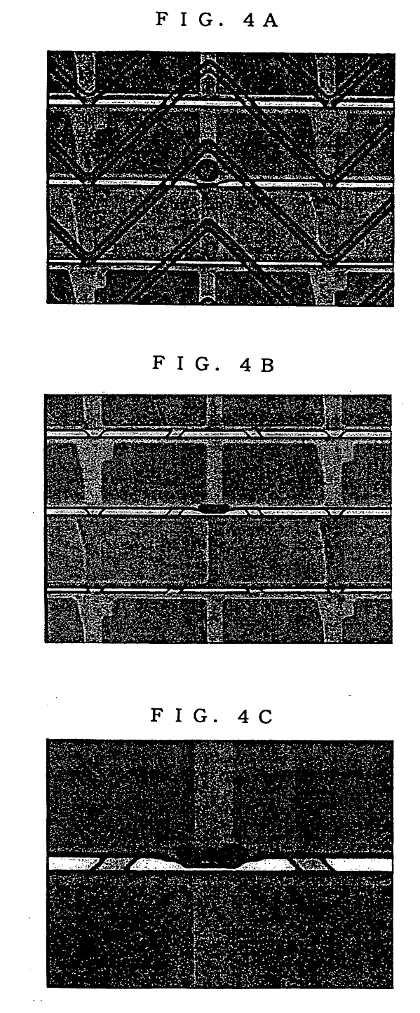

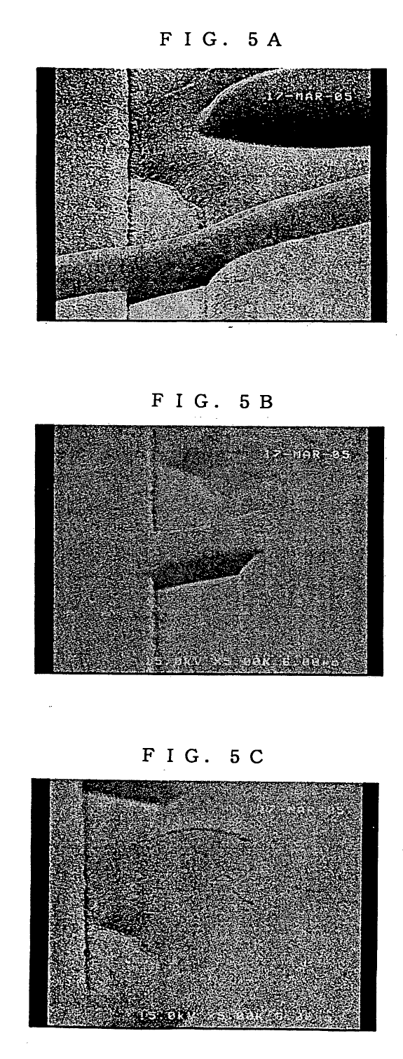

Actual states of the CF substrate 10 after processed by the above-described wet polishing are now shown by microphotographs in FIGS. 4A to 4C and FIGS. 5A to 5C. FIGS. 4A to 4C show optical microphotographs, and FIGS. 5A to 5C show electron microphotographs partially enlarging the target portions shown in FIGS. 4A to 4C, respectively. FIGS. 4A and 5A show states before the polishing, FIGS. 4B and 5B show states 60 seconds after the start of the polishing, and FIGS. 4C and 5C show finished states of the polishing. It is known from FIGS. 4C and 5C that the columnar spacer 5, the alignment-control projection components 6 and alignment film 7 on the ITO transparent electrode 4 were removed.

As has been described in the above, the present embodiment makes it possible to readily and thoroughly remove organic material components, such as the columnar spacer 5, the alignment-control projection components 6 and the alignment film 7, formed on the ITO transparent electrode as the inorganic material layer, while minimizing the number of process steps and reducing damage possibly exerted on the individual layers under the organic material components as possible, so as to allow the CF substrate 10 to be recycled after being returned back to a state very close to its final form.

It is to be noted that Patent Document 2 discloses a technique of regenerating the CF substrate, by preliminarily raising the permeability thereof to a peeling solution by polishing as a physical removal process, more specifically by forming fine random grooves, and then by subjecting the CF substrate to chemical peeling using a peeling solution. In Patent Document 2, the physical removal process is adopted as an auxiliary process for the chemical peeling. In contrast to this, the present invention relates to a technique of removing the organic material components only by the wet polishing as a physical removal process, without being following by chemical peeling, and makes it possible to thoroughly remove any unnecessary organic material components by a smaller number of process steps than in the invention disclosed in Patent Document 2, without causing increase in roughness and irregularity on the substrate surface induced by the chemical peeling.

### MODIFIED EXAMPLE

A modified example of the first embodiment will now be explained. The modified example will exemplify a case where the present invention is adopted to regeneration of the color filter (CF) substrate shown in FIG. 1 similarly to as in the first embodiment, but with a slight difference in the method of wet polishing.

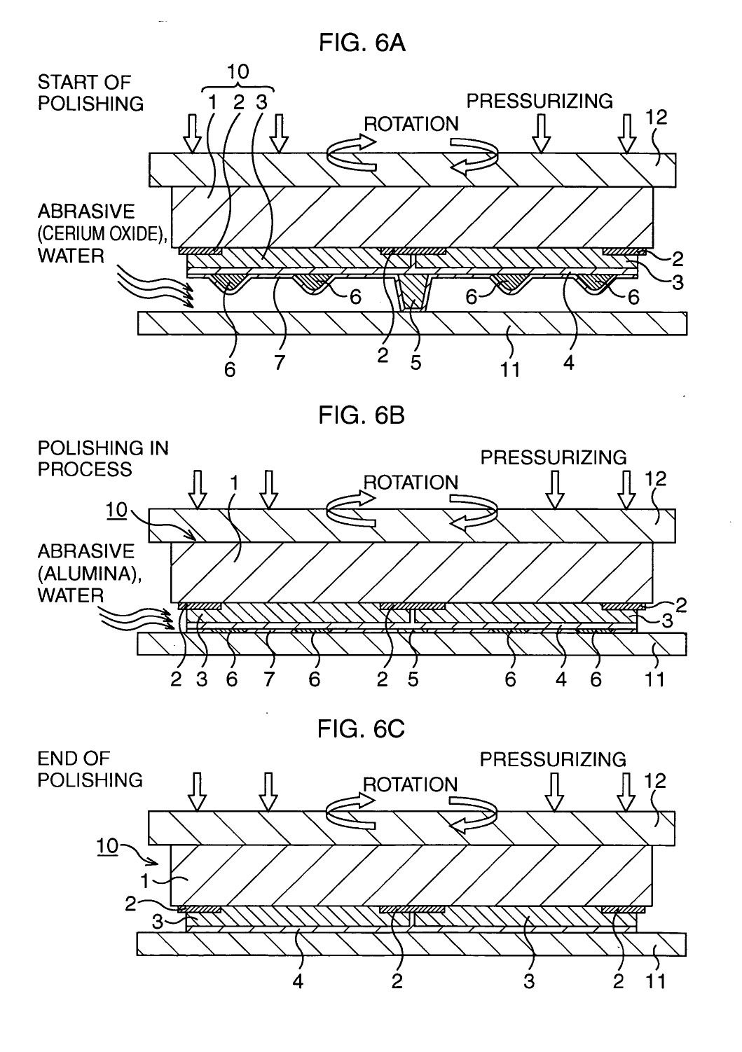

FIGS. 6A to 6C are schematic sectional views sequentially showing process steps of a method of regenerating the CF substrate according to the modified example of the first embodiment.

In the modified example, the CF substrate 10 is regenerated by removing the organic material components which reside on the upper side of the ITO transparent electrode 4 as an inorganic material film, that are the alignment film 7, the columnar spacer 5 and the projection components 6, similarly to as in the above embodiment.

First, as shown in FIG. 6A, the back surface (lower surface) of the CF substrate 10 is fixed to the substrate holder (substrate stage) 12. While keeping the CF substrate 10 fixed to the substrate holder 12, the CF substrate 10 is then allowed to rotate so as to bring the top surface (upper surface) thereof into contact with a polishing head (polishing stage) 11, as being pressurized by the substrate holder 12. Polishing over the entire surface of the CF substrate 10 is started herein by wet etching using, in the early stage of the polishing, an abrasive containing cerium oxide, having a relatively large polishing rate, and water. The illustrated example shows polishing of the CF substrate 10 turned upside down from the state shown in FIG. 1.

In the process of polishing, the CF substrate 10 is gradually polished on the surface thereof so as to be removed earlier in the higher portions. In this case, the polishing proceeds so as to remove the alignment film 7 on the columnar spacer 5, the columnar spacer 5, the alignment film 7 on the projection components 6, and the projection components 6 in this order. Because the columnar spacer 5 and the projection components 6 are relatively less likely to be polished, the wet polishing using the abrasive containing cerium oxide having a relatively large polishing rate and water is successful in thorough removal-by-polishing of these components in an efficient manner.

When the polishing further proceeds to reach the alignment film 7 on the ITO transparent electrode 4, as shown in FIG. 6B, the abrasive is changed. The process herein adopts an abrasive containing a material having a polishing rate smaller than that of cerium oxide, which is alumina for example, and the wet polishing is continued using such abrasive and water. The wet polishing using the abrasive containing alumina having a relatively small polishing rate and water is successful in removing, by polishing, the alignment film 7 while appropriately conditioning the surface state of the CF substrate 10.

The ITO transparent electrode 4 as an inorganic material film then functions as a polishing stopper layer, as shown in FIG. 6C. The polishing is stopped approximately one minute after the surface of the ITO transparent electrode 4 exposed. Because the alignment film 7 can be removed by polishing while appropriately conditioning the surface state of the CF substrate 10, it is made possible to improve the flatness of the surface of the CF substrate 10 having the alignment film 7 removed therefrom, that is the surface of the ITO transparent electrode 4.

While the modified example dealt with the case where the acryl-resin-made columnar spacer 5 and the alignment-control projection components 6 were formed on the CF substrate 10, similarly to as in the above embodiment, it is also allowable to simply remove the alignment film 7 only, or to remove the columnar spacer only.

As has been described in the above, the modified example is not only successful in ensuring the effects expected from the first embodiment, but also in efficiently polishing even less polishable materials among the organic material components, in enabling more sophisticated removal-by-polishing of various organic material components well adopted thereto, and in improving the flatness of the substrate surface after the polishing.

### Second Embodiment

This embodiment will exemplify a case where the present invention is adopted to regeneration of a thin-film transistor (TFT) substrate of a MVA-mode liquid crystal display device.

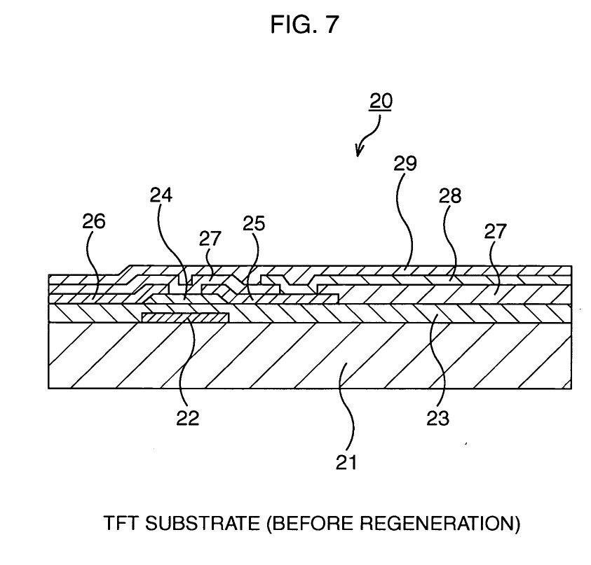

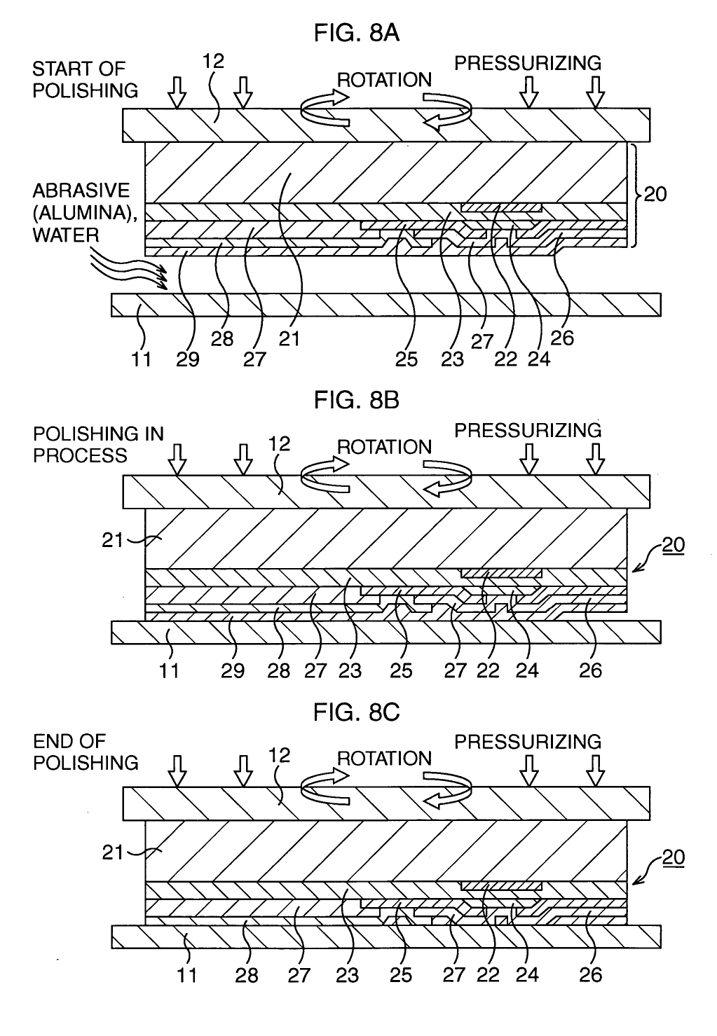

FIG. 7 is a schematic sectional view showing a configuration of the TFT substrate, and FIGS. 8A to 8C are schematic sectional views sequentially showing process steps of the method of regenerating the TFT substrate according to the second embodiment.

As shown in FIG. 7, the TFT substrate 20 has a gate electrode 22 formed directly on the surface of a glass substrate 21 by patterning. The gate electrode 22 is formed typically by using an Al/Nd/Mo stacked film having a thickness of 250 nm or around, and by patterning the film to obtain an electrode geometry. A gate insulating film 23 is then formed so as to cover the gate electrode 22. The gate insulating film 23 is formed typically by using a silicon nitride film having a thickness of 350 nm or around.

Next, an amorphous silicon (a-Si) film 24 is formed by patterning over the gate electrode 22 so as to oppose therewith while placing the gate insulating film 23 in between. A source electrode 25 and a drain electrode 26 are further formed by patterning so as to be connected with portions of the a-Si film 24. The source electrode 25 and the drain electrode 26 are formed typically by using an Mo/Al/Mo stacked film having a thickness of 320 nm or around, and then by patterning the film so as to obtain geometries of the individual electrodes. The source electrode 25 and the drain electrode 26 formed on the a-Si film 24, and the gate electrode 22 opposed with the a-Si film 24 while placing the gate insulating film 23 in between configure a TFT element which serves as an active element.

Next, a protecting film 27 covering the source electrode 25 and the drain electrode 26 is formed. The protecting film 27 is formed typically by using a silicon nitride film having a thickness of 200 nm or around. In the illustrated case, the protecting film 27 has, further formed therein, an opening which allows a portion of the source electrode 25 to expose therein. An ITO pixel electrode 28 typically having a thickness of 40 nm or around is further formed by patterning on the protecting film 27 so as to fill the opening and to be connected with the source electrode 25. Further on the ITO pixel electrode 28 and the protecting film 27, an alignment film 29 aligning the liquid crystal molecules, typically having a thickness of 0.1 μm or around, is formed, to thereby configure the TFT substrate 20.

In this embodiment, the TFT substrate 20 is regenerated by removing the alignment film 29.

First, as shown in FIG. 8A, the back surface (lower surface) of the TFT substrate 20 is fixed to a substrate holder (substrate stage) 12. While keeping the TFT substrate 20 fixed to the substrate holder 12, the TFT substrate 20 is then allowed to rotate so as to bring the top surface (upper surface) thereof into contact with a polishing head (polishing stage) 11, as being pressurized by the substrate holder 12. Polishing over the entire surface of the TFT substrate 20 is started herein by wet etching, using herein an alumina-containing abrasive and water. The illustrated example shows polishing of the TFT substrate 20 turned upside down from the state shown in FIG. 7.

In the process of polishing, the TFT substrate 20 is gradually polished on the surface thereof so as to be removed earlier in the higher portions, as shown in FIG. 8B. In this case, the polishing proceeds first in the alignment film 29 on the TFT element.

In the TFT substrate 20, the level of portions over the TFT element and intermediate electrodes is higher by approximately 0.5 nm to 0.6 nm than the level of the portion over the ITO pixel electrode 28, so that the polishing proceeds first in the higher portions. Also the intermediate electrodes and so forth are polished off while the alignment film 29 on the ITO pixel electrode 28 is polished, but the electrodes and interconnections, which are inorganic films, are low in the polishing rate, and raises no special problem.

The ITO pixel electrode 28 as an inorganic material film then functions as a polishing stopper layer, as shown in FIG. 8C. The polishing is stopped approximately 30 seconds after the surface of the ITO pixel electrode 28 exposed. Over-polishing slightly into the ITO pixel electrode 28 is successful in removing by polishing the alignment film 29 on the ITO pixel electrode 28.

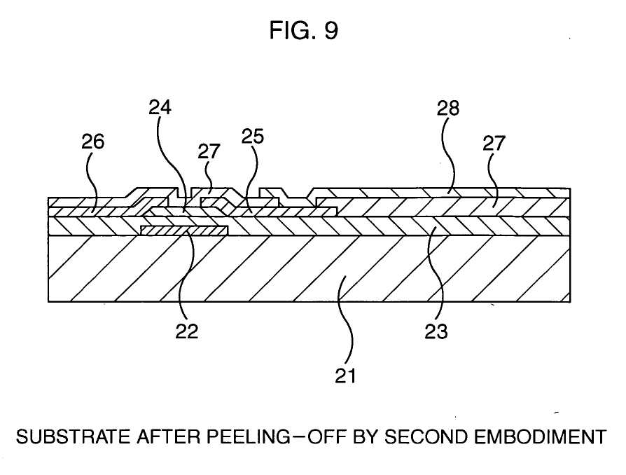

A finished state of the wet polishing of the TFT substrate 20 in the present embodiment is shown in FIG. 9.

In this embodiment, the TFT substrate 20 is returned back to a state very close to the final form, that is, a state having the ITO pixel electrode 28 formed on the protecting film 27. As is clear from the above, the present embodiment no more needs repetitive formation of ITO pixel electrode 28 and constituents of the TFT element, and is successful in considerably reducing the number of process steps as compared with the conventional method.

As has been described in the above, the present embodiment makes it possible to readily and thoroughly remove organic material component, such as the alignment film 29, formed on the ITO pixel electrode 28 as the inorganic material layer, while minimizing the number of process steps and reducing damage possibly exerted on the individual layers under the organic material component as possible, so as to allow the TFT substrate 20 to be recycled after being returned back to a state very close to its final form.

The organic material components formed on the inorganic material film, in particular such as alignment film and alignment-control projection component, can be readily and thoroughly removed, while minimizing the number of process steps, and reducing as possible damage possibly exerted on the individual layers under the organic material components, so as to allow a color filter substrate or a TFT substrate to be recycled after being returned back to a state very close to its final form.

What is claimed is:

1. A method of regenerating a substrate used for a liquid crystal display device, selectively removing, using an inorganic material film formed on the upper portion of said substrate as a polishing stopper layer, only an organic material component formed on the inorganic material film, only by wet polishing using an abrasive.

2. The method of regenerating a substrate according to claim 1, wherein said inorganic material film is a transparent electrode composed of ITO.

3. The method of regenerating a substrate according to claim 1, wherein said organic material component is an alignment film.

4. The method of regenerating a substrate according to claim 1, wherein said organic material component is a columnar spacer.

5. The method of regenerating a substrate according to claim 1, wherein said organic material component is a projection component used for alignment control.

6. The method of regenerating a substrate according to claim 1, wherein said abrasive contains cerium oxide or alumina.

7. The method of regenerating a substrate according to claim 1, wherein only said organic material component is removed by repeating said polishing a plural number of times, while varying the polishing rate by using different types of said abrasive.

8. The method of regenerating a substrate according to claim 7, wherein a first abrasive containing cerium oxide is used in the first cycle of said polishing, and a second abrasive containing alumina, showing a small polishing rate than said first abrasive, is used in the second cycle of said polishing.
